(19) United States
(12) Patent Application Publication
(10) Pub. No.: US 2005/0035448 A1
(43) Pub. Date: Feb. 17, 2005

(54) Chip package structure

(76) Inventors: Chi-Hsing Hsu, Hsin-Tien City (TW); Kenny Chang, Hsin-Tien City (TW)

Correspondence Address: J C PATENTS, INC., 4 VENTURE, SUITE 250, IRVINE, CA, 92618, US

(21) Appl. No.: 10/695,018

(22) Filed: Oct. 27, 2003

(30) Foreign Application Priority Data
Aug. 14, 2003 (TW) 92122339

(51) Int. Cl. H01L 33/00

(52) U.S. Cl. 257/734

(57) ABSTRACT

A chip package structure is provided. The chip package at least comprises a carrier, a die, a passive component, a plurality of first conducting wires, a second conducting wire, and a dielectric material. Two electrodes of the passive component are electrically connected to the power pad and the ground pad, respectively. Since one end of the conducting wire is directly connected to one electrode of the passive component, the length of the conducting wire can be effectively shortened. Hence the signal transmission path is shorter and there is more layout space for conducting wires.

### CROSS-REFERENCE TO RELATED APPLICATION

This application claims the priority benefit of Taiwan application serial no. 92122339, filed on Aug. 14, 2003.

### BACKGROUND OF THE INVENTION

1. Field of the Invention

This invention generally relates to a chip package structure, and more particularly to a wire bonding chip package structure integrated with a passive component.

2. Description of the Related Art

With the rapid advances in the semiconductor manufacturing technology, the semiconductor devices are getting smaller and smaller, and the performnance thereof are also getting much better than before. The semiconductor packaging technology such as chip packaging technology, chip carrier manufacturing, and passive component assembly are very important to the semiconductor manufacturing industry.

For the chip packaging technology, each die cut from the wafer will be disposed on the carrier by wire bonding or flip chip bonding, wherein the carrier is a leadframe or a substrate. A die comprises several die pads, which can be used to electrically connect the external devices via the circuits or the bonding pads of the carrier. Further, the die connected by wire bonding will be packaged by the dielectric material to protect the die and the conducting wires. After the die is packaged, it becomes a chip package structure.

Referring to FIGS. 1A and 1B, FIG. 1A is a partial cross-sectional view of a conventional wire bonding chip package structure and FIG. 1B is top view of a conventional wire bonding chip package structure. A chip package structure 100 includes a carrier 110, a die 120, a plurality of conducting wires 134, 136, 138, and a dielectric material (not shown). The surface of the carrier 110 includes a die bonding area 112. The backside 122 of the die 120 is attached to the die bonding area 112. The active surface 124 of the die 120 includes a plurality of die pads 126 corresponding to the bonding pads on the surface of the carrier 110. The bonding pads from inside to outside are ground pad 114, power pad 116, and signal pad 118. Further, two ends of each of conducting wires 134, 136, and 138 are connected to one of the die pads 126 and its corresponding ground pad 114, power pad 116, and signal pad 118, respectively.

It should be noted that, to enhance the electrical performance of the chip package structure 100, the surface mount technology (SMT) is used to attach the passive component 130 on the surface of the carrier 110 to reduce the crosstalk of the signals due to switch and to maintain the signal transmission quality. The passive component 130 is an inductor or a capacitor. The passive component 130 is disposed between and connected to the power pad 116 and the ground pad 114 of the carrier 110.

However, when the die 120 and the carrier 110 is connected by wire bonding process, the conducting wire 136 which is corresponding to the die pad 126 and the power pad 116 has to cross over the passive component 130 and then the two ends of the conducting wire 136 are connected to the surface of the power pad 116 and the die pad 126, respectively. Because the conducting wire 136 has to be form an arc to cross over the passive component 130, the length of the conducting wire 136 is longer. Hence, the signal path through the conducting wire 136 is longer, which affects the electrical performance of the chip package structure 100 and reduces the layout space for conducting wires.

### SUMMARY OF THE INVENTION

An object of the present invention is to provide a chip package structure to shorten the length of the conducting wire and increase the layout space for conducting wires.

The present invention provides a chip package structure, at least comprising: a carrier having a surface, a power pad, and a ground pad, wherein the surface having a die bonding area, the power pad and the ground pad being on the surface, the power pad and the ground pad being disposed outside the die bonding area; a die having an active surface and a backside corresponding to the active surface, the backside of the die being attached to the die bonding area on the surface of the carrier, the die having a plurality of die pads on the active surface; at least a passive component disposed between the power pad and the ground pad, the passive component having at least two electrodes electrically connected to the power pad and the ground pad respectively; at least a conducting wire having two ends connected to one of the die pads and one of the electrodes respectively; and a dielectric material covering the die, the passive component, and the conducting wire.

In the chip package structure of the present invention, one end of the conducting wire can be directly connected to one of the electrodes of the passive component. Hence, the signal transmission path is much shorter and thus there is more layout space for conducting wires.

The above is a brief description of some deficiencies in the prior art and advantages of the present invention. Other features, advantages and embodiments of the invention will be apparent to those skilled in the art from the following description, accompanying drawings and appended claims.

### BRIEF DESCRIPTION OF THE DRAWINGS

FIG. 1A is a partial cross-sectional view of a conventional wire bonding chip package structure.

FIG. 1B is a top view of a conventional wire bonding chip package structure.

FIG. 2A is a partial cross-sectional view of a wire bonding chip package structure in accordance with a preferred embodiment of the present invention.

FIG. 2B is a top view of a wire bonding chip package structure in accordance with a preferred embodiment of the present invention.

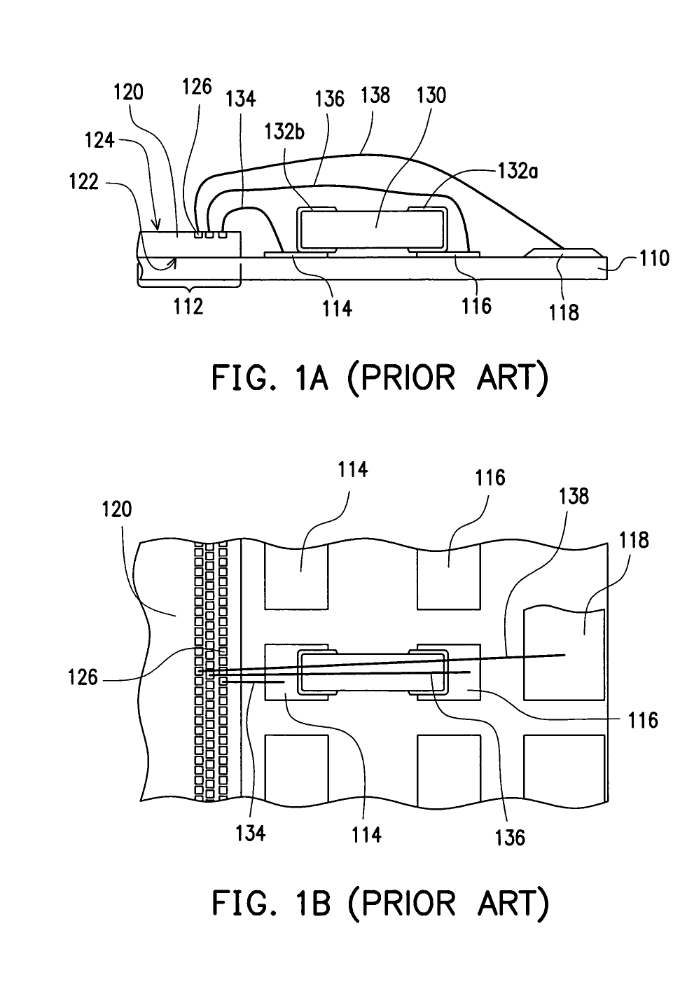

### DESCRIPTION OF THE PREFERRED EMBODIMENTS

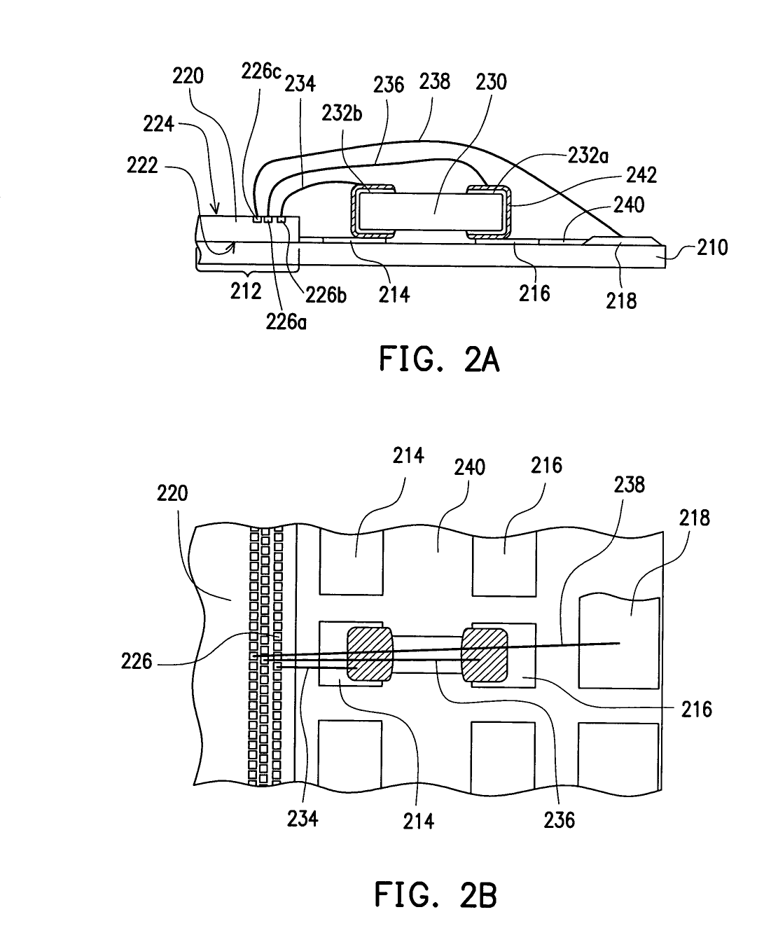

FIG. 2A is a partial cross-sectional view of a wire bonding chip package structure in accordance with a preferred embodiment of the present invention. FIG. 2B is a top view of a wire bonding chip package structure in accordance with a preferred embodiment of the present invention. The chip package structure 200 includes a carrier 210, a die 220, a passive component 230, first conducting wires 234 and 236, a second conducting wire 238, and a dielectric material (not shown). The carrier 210 is a package substrate, for example. The surface of the carrier 210 includes a die bonding area 212. The backside 222 of the die 220 is attached to the die bonding area 212. The active surface 224 of the die 220 includes a plurality of die pads 226 corresponding to the bonding pads on the surface of the carrier 210. The bonding pads are ground pad 214, power pad 216, and signal pad 218. In this embodiment as shown in FIG. 2B, the power pad 216 and the ground pad 214 are outside the die bonding area 212 and on the one side of the die bonding area 212. The power pad 216 and the ground pad 214 are formed by a portion of a power ring (not shown) and a portion of a ground ring (not shown) surrounding the die boding area 212, respectively. A partial surface of the power ring and a partial surface of the ground ring are exposed in openings of a solder mask layer 240 as the power pad 216 and the ground pad 214 respectively, for the purpose of connecting the first conducting wires 234 and 236 or the passive component 230.

Referring to FIGS. 2A and 2B, the signal pad 218 is on the same side as the power pad 216 and the ground pad 214, but is farther from the die bonding area than the power pad 216 and the ground pad 214. Further, the signal pad 218 and the die bonding area 212 also can be exposed in the openings of the patterned solder mask layer 240, respectively.

Referring to FIG. 2A, the passive component 230 is cross-connected to the power pad 216 and the ground pad 214. The passive component 230 comprises at least two electrodes 232a and 232b. These two electrodes 232a and 232b can be connected to the surface of the power pad 216 and the surface of the ground pad 214 respectively by using SMT to suppress the coupling inductance generated by first conducting wires 234 and 236, and the second conducting wire 238. The passive component 230 can be an inductor or a capacitor. The surface of the electrodes 232a and 232b comprises a metal layer 242. The metal layer 242 at least includes Ni, Au, or Ni/Au alloy to enhance the connection property of later wire bonding between the first conducting wires 234 and 236, and the electrodes 232a and 232b.

It should be noted that, in order to shorten the length of the conducting wires 234 and 236, at least one end of the first conducting wire 236 is connected to the electrode 232a of the passive component 230. The two ends of the first conducting wire 236 are connected to a die pad 226a and the electrode 232a of the passive component 220 respectively, wherein the electrode 232a is the electrode farther from the die 220. The two ends of the other first conducting wire 234 are connected to another die pad 226b and the electrode 232b of the passive component 220 or the ground pad 214 (not shown) respectively, wherein the electrode 232b is the electrode closer to the die 220. Because the first conducting wire 236 is not required to form an arc to cross over the whole passive component 230, but is directly connected to the electrode 232a, the length of the first conducting wire 236 can be shortened. Hence the signal transmission path is shorter and there is more layout space for conducting wires. Further, the two ends of the second conducting wire 238 are connected to another die pad 226c and the outer signal pad 218 of the carrier 210 respectively. The second conducting wire 238 can cross over the passive component 230 without contacting the electrodes 232a or 232b of the passive component 230.

Accordingly, the chip package structure disposes a passive component between the power pad and the ground pad. The passive component is electrically connected to the power pad and the ground pad. The first conducting wire is connected to a die pad and one electrode of the passive component. The second conducting wire is connected to another die pad and the signal pad. Then a dielectric material is used to cover the die, the passive component, and all conducting wires to protect the die, and all conducting wires. After the dielectric material covers the die, the passive component, and all conducting wires, the chip package structure is formed.

The above description provides a full and complete description of the preferred embodiments of the present invention. Various modifications, alternate construction, and equivalent may be made by those skilled in the art without changing the scope or spirit of the invention. Accordingly, the above description and illustrations should not be construed as limiting the scope of the invention which is defined by the following claims.

1. A chip package structure, at least comprising:
a carrier having a surface, a power pad and a ground pad, said surface having a die bonding area, said power pad and said ground pad being on said surface, said power pad and said ground pad being disposed outside said die bonding area;
a die having an active surface and a backside corresponding to said active surface, said backside being attached to said die bonding area on said surface of said carrier, said die having a plurality of die pads on said active surface;
at least a passive component disposed between said power pad and said ground pad, said passive component having at least two electrodes electrically and physically connected to said power pad and said ground pad respectively; and
at least a first conducting wire having two ends electrically and physically connected to one of said plurality of die pads and one of said electrodes respectively.

2. The chip package structure of claim 1, further comprising a dielectric material covering said die, said passive component, and said first conducting wire.

3. The chip package structure of claim 1, wherein said carrier comprises a signal pad, said signal pad being disposed outside said die bonding area and farther from said die bonding area than said power pad and said ground pad.

4. The chip package structure of claim 3, further comprising at least a second conducting wire having two ends connected to another one of said plurality of die pads and said signal pad respectively, said second conducting wire crossing over said passive component.

5. The chip package structure of claim 4, further comprising a dielectric material covering said die, said passive component, said first conducting wire, and said second conducting wire.

6. The chip package structure of claim 1, wherein the surface of said electrodes comprises a metal layer, said metal layer at least including Ni, Au, or Ni/Au alloy.

7. The chip package structure of claim 1, wherein said passive component is selected from one of an inductor and a capacitor.

8. The chip package structure of claim 1, wherein said carrier is a package substrate.

9. A wire bonding package structure for electrically connecting a die to a carrier, said carrier having a surface and a die bonding area on said surface, said die having an active surface and a backside corresponding to said active surface, said backside of said die being attached to die bonding area, said wire bonding package structure at least comprising:
a power pad on said surface of said carrier;
a ground pad on said surface of said carrier;
a signal pad on said surface of said carrier, said power pad, said ground pad and said signal pad being disposed outside said die bonding area, wherein said signal pad being farther from said die bonding area than said power pad and said ground pad;
a passive component disposed between said power pad and said ground pad, said passive component having at least two electrodes electrically and physically connected to said power pad and said ground pad respectively,
a plurality of die pads on said active surface of said die;
a first conducting wire having two ends electrically and physically connected to one of said die pads and one of said electrodes respectively; and
a second conducting wire having two ends electrically and physically connected to another one of said die pads and said signal pad respectively, wherein said second conducting wire crossing over said passive component.

10. The wire bonding package structure of claim 9, wherein the surface of said electrodes comprises a metal layer, said metal layer at least including Ni, Au, or Ni/Au alloy.

11. The wire bonding package structure of claim 9, wherein said passive component is selected from one of an inductor and a capacitor.

12. The wire bonding package structure of claim 9, further comprising a dielectric material covering said die, said passive component, said first conducting wire, and said second conducting wire.

13. The wire bonding package structure of claim 9, wherein said carrier is a package substrate.
